(19) United States
(12) Patent Application Publication
(10) Pub. No.: US 2016/0079493 A1
(43) Pub. Date: Mar. 17, 2016

(54) LIGHT EMITTING DEVICE AND MANUFACTURING METHOD THEREOF

(71) Applicant: KABUSHIKI KAISHA TOSHIBA, Tokyo (JP)

(72) Inventor: Mie MATSUO, Kamakura Kanagawa (JP)

(21) Appl. No.: 14/634,707

(22) Filed: Feb. 27, 2015

(30) Foreign Application Priority Data
Sep. 12, 2014 (JP) 2014-185985

(51) Int. Cl. H01L 33/56; H01L 33/06; H01L 33/32; H01L 33/62; H01L 33/40; H01L 33/00; H01L 33/60

(52) U.S. Cl. CPC H01L 33/56; H01L 33/0025; H01L 33/007; H01L 33/0095; H01L 33/06; H01L 33/60; H01L 33/62; H01L 33/405; H01L 33/32; H01L 2933/0033; H01L 2933/0058; H01L 2933/0066; H01L 2933/005

(57) ABSTRACT

A light emitting device includes a frame, a light emitting element provided above the frame and including a substrate, a light emitting layer provided above the substrate, a first reflective layer provided on a bottom surface of the substrate, a second reflective layer provided on a side surface of the substrate, and an electrode, and a bonding wire with one end electrically connected to the electrode and another end electrically connected to the frame.

### CROSS-REFERENCE TO RELATED APPLICATION

This application is based upon and claims the benefit of priority from Japanese Patent Application No. 2014-185985, filed Sep. 12, 2014, the entire contents of which are incorporated herein by reference.

### FIELD

Embodiments described herein relate generally to a light emitting device and a method of manufacturing the light emitting device.

### BACKGROUND

In manufacturing a light emitting device using a semiconductor light emitting element (hereinafter, light emitting element), a reflective material is typically applied to cover the whole side surface of the light emitting element mounted on a frame.

The reflective material reflects light emitted from a light emitting layer of a light emitting element towards the reflective material, towards the light extraction surface. Since the light reflected by the reflective material is extracted as well as light emitted from the light emitting device towards outside thereof, light emission efficiency of the light emitting device may be improved.

However, when the reflective material is formed, the reflective material may extend to a top surface of the light emitting element and cover a pad electrode formed on the top surface. When the reflective material covers the pad electrode, connection of a bonding wire to the pad electrode may be disturbed. In other words, although the reflective material may be able to improve the emission efficiency of the light emitting device, it may prevent wire bonding of the light emitting element. As the result, production yield of the light emitting device may be decreased.

### DESCRIPTION OF THE DRAWINGS

FIG. 1 is a schematic cross-sectional view of a light emitting device 1 according to an embodiment.

FIG. 2 is a schematic cross-sectional view of a light emitting element 12 in the light emitting device 1 of FIG. 1.

FIGS. 3A to 3C are a cross-sectional view of a structure during manufacturing of the light emitting device 1 according to the embodiment.

FIGS. 4A to 4C are a cross-sectional view of a structure during manufacturing the light emitting device 1, following FIG. 3C.

FIGS. 5A to 5C are a cross-sectional view of a structure during manufacturing of the light emitting device 1, following FIG. 4C.

FIGS. 6A to 6C are a cross-sectional view of a structure during manufacturing of the light emitting device 1, following FIG. 5C.

FIGS. 7A to 7C are a cross-sectional view of a structure during manufacturing of the light emitting device 1, following FIG. 6C.

FIGS. 8A and 8B are a cross-sectional view of a structure during manufacturing of the light emitting device 1, following FIG. 7C.

FIGS. 9A to 9E are a cross-sectional view of a structure during manufacturing of the light emitting device 1, following FIG. 8B.

### DETAILED DESCRIPTION

In general, according to one embodiment, a light emitting device includes a frame, a light emitting element provided above the frame and including a substrate, a light emitting layer provided above the substrate, a first reflective layer provided on a bottom surface of the substrate, a second reflective layer provided on a side surface of the substrate, and an electrode, and a bonding wire with one end electrically connected to the electrode and another end electrically connected to the frame.

Hereinafter, one embodiment in the disclosure will be described with reference to the drawings. The embodiment is not intended to limit the scope of the present invention.

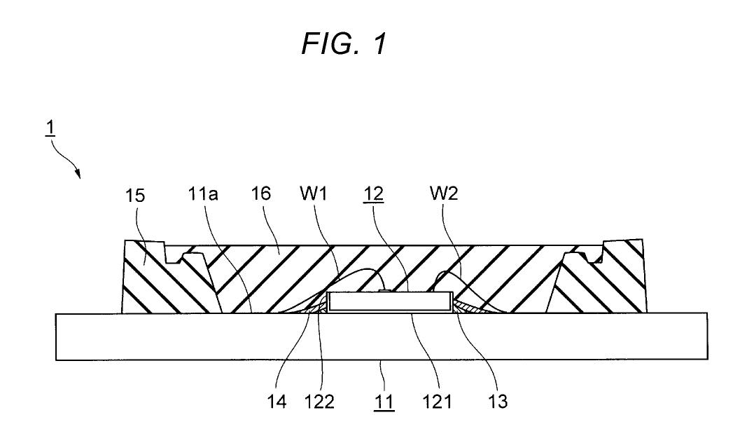

FIG. 1 is a schematic cross-sectional view of a light emitting device 1 according to an embodiment. The light emitting device 1 illustrated in FIG. 1 maybe used, for example, as a light source for illumination.

The light emitting device 1 includes a frame 11, a light emitting element 12, an adhesive layer 13 (or, a mounting material), a covering resin (e.g., paste) 14 including a high reflective material, a mold resin layer 15, a fluorescent material layer 16, a first bonding wire W1 and a second bonding wire W2. The bottom portion of the light emitting element 12 includes a first reflective layer 121. Further, the four side wall portions of the light emitting element 12 include a second reflective layer 122.

The frame 11 is formed in a plate shape. The frame 11 includes metallic material such as Cu. A plating layer of Ag, not illustrated, is formed on the top surface 11a of the frame 11. By forming the plating layer of Ag, light emitted from the light emitting element 12 is reflected to reduce light absorption by the frame 11, and the bonding strength between the frame 11 and the first bonding wire W1 or between the frame 11 and the second bonding wire W2 is improved.

The light emitting element 12 is mounted on the top surface 11a of the frame 11. Further, the light emitting element 12 is adhered to the frame 11 through the adhesive layer 13 provided between the top surface 11a and the second reflective layer 122. The light emitting element 12 is electrically connected to a cathode portion of the frame 11 with the first bonding wire W1. Further, the light emitting element 12 is electrically connected to an anode portion of the frame 11 with the second bonding wire W2.

The adhesive layer 13 in this embodiment has a light absorbing property, and is, for example, a black resin adhesive. In other words, light absorptivity (e.g., light absorbency index) is larger than light reflectance in the adhesive layer 13. The covering resin 14 includes a high reflective material, such that a light absorbency index of the adhesive layer 13 is larger than a light absorbency index of the covering resin 14. The covering resin 14 covers the adhesive layer 13 between the top portion of the adhesive layer 13 and the second reflective layer 122. The covering resin 14 suppresses the light absorption by the adhesive layer 13 by covering the adhesive layer 13. When the adhesive layer 13 is an adhesive layer having a light reflectance, the covering resin 14 may be omitted.

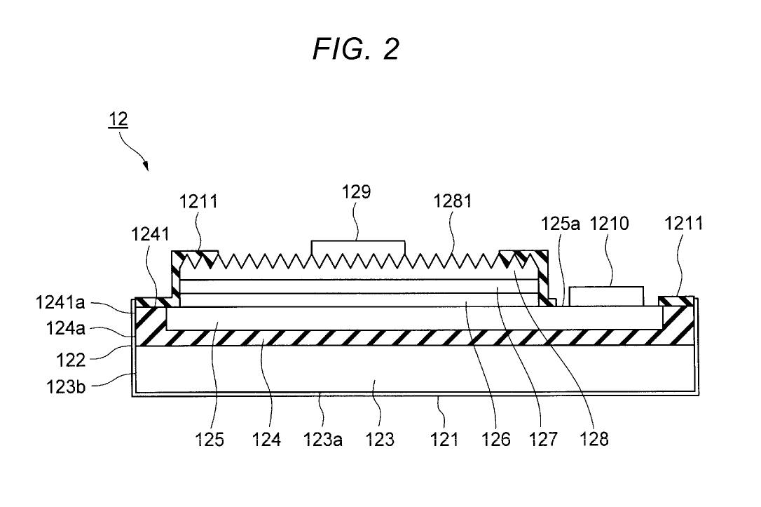

FIG. 2 is a schematic cross-sectional view of the light emitting element 12 in the light emitting device 1 of FIG. 1. As illustrated in FIG. 2, the light emitting element 12 includes a first reflective layer 121, a supporting substrate 123, a joint layer 124, a lower electrode layer 125, a p-type nitride semiconductor layer 126, a p-type pad electrode 1210 and protective layer 1211 (passivation), a light emitting layer 127, an n-type nitride semiconductor layer 128, and an n-type pad electrode 129 in the order of starting from the bottom layer. Further, the light emitting element 12 includes the above-mentioned second reflective layer 122.

A light extraction surface 1281 is formed on the top surface of the n-type nitride semiconductor layer 128. The light extraction surface 1281 extracts the light emitted from the light emitting layer 127. Specifically, the light extraction surface 1281 emits the light going out from the light emitting layer 127 and arriving at the light extraction surface 1281 to outside the light emitting element 12 in a diffused manner.

The p-type nitride semiconductor layer 126 is an example of a second nitride semiconductor layer. The n-type nitride semiconductor layer 128 is an example of a first nitride semiconductor layer. The p-type pad electrode 1210 is an example of a second electrode. The n-type pad electrode 129 is an example of a first electrode.

The supporting substrate 123 includes Si.

The first reflective layer 121 is provided under the bottom surface 123a of the supporting substrate 123. The second reflective layer 122 is also provided on the side surface 123b of the supporting substrate 123. The second reflective layer 122 is continually connected to the first reflective layer 121.

The first reflective layer 121 reflects the light which reaches the first reflective layer 121 after being emitted from the light emitting layer 127, toward the light extraction surface 1281. The second reflective layer 122 reflects the light which reaches the second reflective layer 122 after being emitted from the light emitting layer 127, toward the light extraction surface 1281. The reflected light by the first reflective layer 121 and the second reflective layer 122 arrives at the light extraction surface 1281, for example, passing through the light emitting element 12. The light reflected from the reflective layers 121 and 122 and arriving at the light extraction surface 1281 is used as the illumination light of the light emitting device 1, together with the light directly arriving at the light extraction surface 1281 from the light emitting layer 127.

The material of the first reflective layer 121 and the second reflective layer 122 is not limited and a metal such as Au, Ag, Pd, Pt, or Al may be adopted as an example of preferred material.

Here, when the second reflective layer 122 is not provided on the side surface 123b of the supporting substrate 123, it is necessary to reflect the light emitted from the light emitting layer 127 in the side surface of the light emitting element 12. In this case, when the covering resin 14 including a high reflective material is set at a higher position enough to reflect, the amount of the covering resin 14 that is used becomes larger. Due to the increase in the use amount of the covering resin 14, the covering resin 14 may overflow onto the top surface of the light emitting element 12 and may cover at least one of the p-type pad electrode 1210 and the n-type pad electrode 129. Usually, the light emitting element 12 is very thin with a thickness of 100 to 200 μm according to the requirement for reduction in thickness. Thus, the covering resin 14 may overflow onto the top surface of this thin light emitting element 12.

When the covering resin 14 covers the p-type pad electrode 1210 and the n-type pad electrode 129, it is difficult to connect the second bonding wire W2 to the p-type pad electrode 1210. Further, it is difficult to connect the first bonding wire W1 to the n-type pad electrode 129. In short, the bonding strength between n-type pad electrode 129 and the first bonding wire W1 or between p-type pad electrode 1210 and the second bonding wire W2 is weakened when the covering resin 14 covers the p-type pad electrode 1210 and the n-type pad electrode 129.

In order to cope with the above, in the embodiment, the second reflective layer 122 serves to secure sufficient reflectance on the side surface of the light emitting element 12. This reduces a necessity for securing the reflectance on the side surface of the light emitting element 12 through the covering resin 14 including a high reflective material. Even when the covering resin 14 including a high reflective material is provided in order to cover the light absorptive adhesive layer 13, the use amount maybe limited to the amount necessary for covering the adhesive layer 13. The amount of the covering resin 14 necessary for covering the adhesive layer 13 is less than the amount of the covering resin 14 required for securing the reflectance.

Since the use amount of the covering resin 14 including a high reflective material may be reduced, the covering resin 14 does not overflow onto the top surface of the light emitting element 12 and does not cover at least one of the p-type pad electrode 1210 and the n-type pad electrode 129. Thus, the second bonding wire W2 maybe properly connected to the p-type pad electrode 1210. Further, the first bonding wire W1 may be properly connected to the n-type pad electrode 129. In short, according to the embodiment, the wire bonding may be properly performed. As the result of properly performing the wire bonding, production yield may be improved. Further, since the use amount of the covering resin 14 including a generally expensive high reflective material, may be reduced, the manufacturing cost of the light emitting device 1 may be reduced.

The joint layer 124 is provided between the supporting substrate 123 and the lower electrode layer 125. The joint layer 124 bonds the supporting substrate 123 to the lower electrode layer 125. The joint layer 124 has a wall portion 1241 protruding upward in the side end portion of the joint layer 124.

The joint layer 124 is an oxide film or generally any insulating film.

The second reflective layer 122 is provided along the side surface 123b of the supporting substrate 123 and the side surface 124a of the joint layer 124. Further, the second reflective layer 122 extends to the side surface 1241a of the wall portion 1241. Thus, the second reflective layer 122 is provided not only on the side surface 123b of the supporting substrate 123 but also on the side surface 124a of the joint layer 124 and the side surface 1241a of the wall portion 1241; therefore, the reflectance on the side surface of the light emitting element 12 may be improved.

As will be described below, in order to provide the second reflective layer 122 across the side surface 124a of the joint layer 124 and the side surface 1241a of the wall portion 1241, dry etching is performed on the joint layer 124. When the joint layer 124 is a metal film of, for example, Sn, the joint layer 124 has to be etched by the dry etching, which is difficult to be carried out on a metal film. As the result, the second reflective layer 122 made of metal would be difficult to form.

On the contrary, in the embodiment, since the joint layer 124 is made of an oxide film, which may be more easily etched by dry etching than the metal film, the joint layer 124 may be more easily etched using dry etching. As a result, the second reflective layer 122 may be easily formed.

Further, insulation property of the joint layer 124 may prevent electrical conduction between the second reflective layer 122 and the lower electrode layer 125.

The lower electrode layer 125 is provided between the joint layer 124 and the p-type nitride semiconductor layer 126, p-type pad electrode 1210, and protective layer 1211 (i.e., between the supporting substrate 123 and the light emitting layer 127). The lower electrode layer 125 electrically connects the p-type pad electrode 1210 and the p-type nitride semiconductor layer 126.

The lower electrode layer 125 reflects the light emitted from the light emitting layer 127 towards the lower electrode layer 125, towards the light extraction surface 1281.

Thus, since the lower electrode layer 125 serves also as a reflective layer, there is no need to provide a reflective layer separately under the p-type nitride semiconductor layer 126. The lower electrode layer 125 may be formed of, for example, Ag, Al, or Ni.

The p-type nitride semiconductor layer 126 is provided between the light emitting layer 127 and the lower electrode layer 125. The p-type nitride semiconductor layer 126 may be, for example, a GaN semiconductor layer with a p-type dopant such as magnesium or zinc.

The light emitting layer 127 may be, for example, a single quantum well structure (SQW) with a quantum well layer made of InGaN and barrier layers sandwiching the quantum well layer stacked thereon. Alternatively, the light emitting layer 127 maybe a multiple quantum well structure (MQW) with the quantum well layers and the barrier layers alternately staked thereon.

The n-type nitride semiconductor layer 128 is provided on the top surface of the light emitting layer 127. The n-type nitride semiconductor layer 128 may be, for example, a GaN semiconductor layer with a dopant of Si added therein. The light extraction surface 1281 on the top surface of the n-type nitride semiconductor layer 128 may be, for example, a roughened surface.

The n-type pad electrode 129 is provided on the top surface of the n-type nitride semiconductor layer 128, above the supporting substrate 123. The n-type pad electrode 129 is electrically connected to the n-type nitride semiconductor layer 128. The n-type pad electrode 129 may be formed of, for example, Al.

The p-type pad electrode 1210 is provided on the top surface 125a of the lower electrode layer 125, above the supporting substrate 123, at a position adjacent to the p-type nitride semiconductor layer 126. The p-type pad electrode 1210 is electrically connected to the p-type nitride semiconductor layer 126 through the lower electrode layer 125. The p-type pad electrode 1210 is formed of, for example, Al.

The protective layer 1211 extends from the top surface 125a of the lower electrode layer 125 to the side surface of the p-type nitride semiconductor layer 126, the side surface of the light emitting layer 127, and the side and top surfaces of the n-type nitride semiconductor layer 128. The protective layer 1211 protects a foreign substance conducting the p-type pad electrode 1210 and the n-type pad electrode 129 from being attached, hence to prevent the short of the both electrodes 1210 and 129. The protective layer 1211 may be formed of, for example, SiO₂ or SiN.

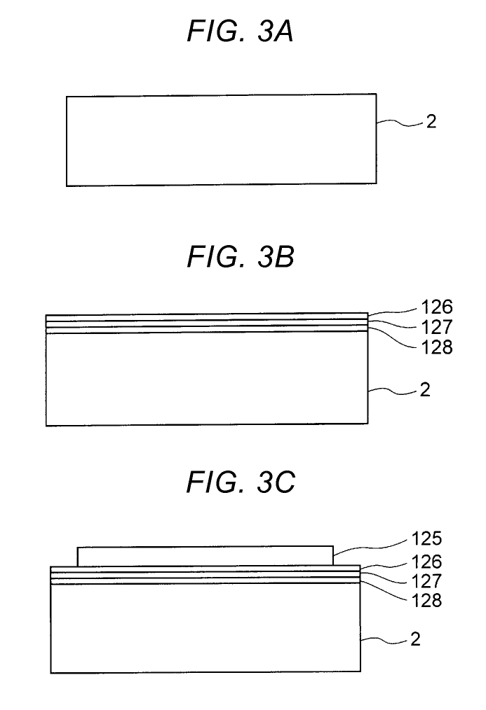

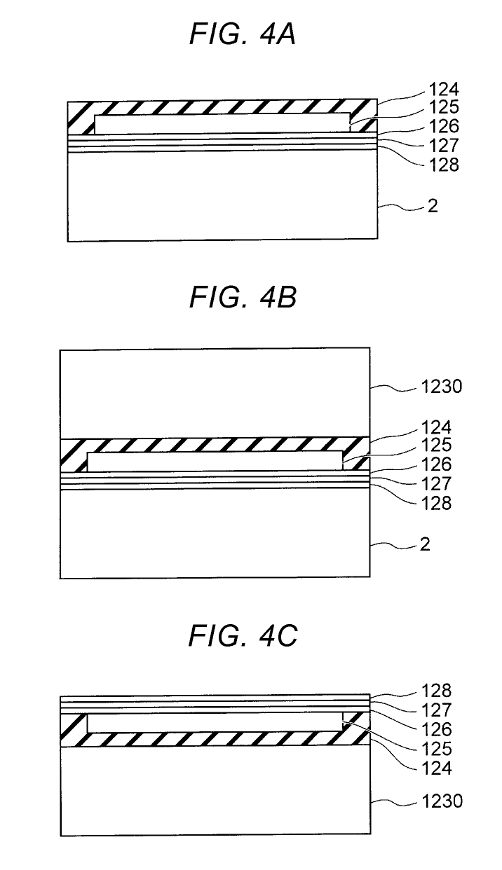

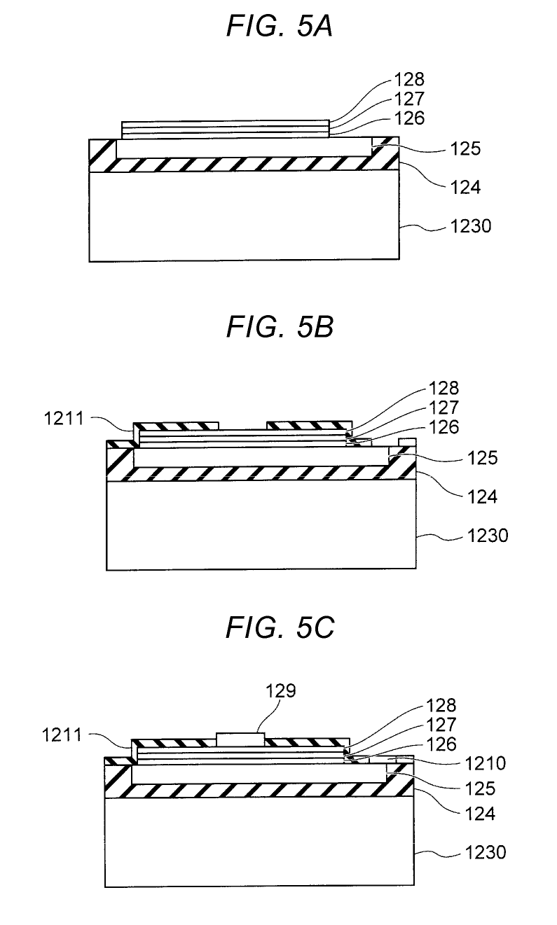

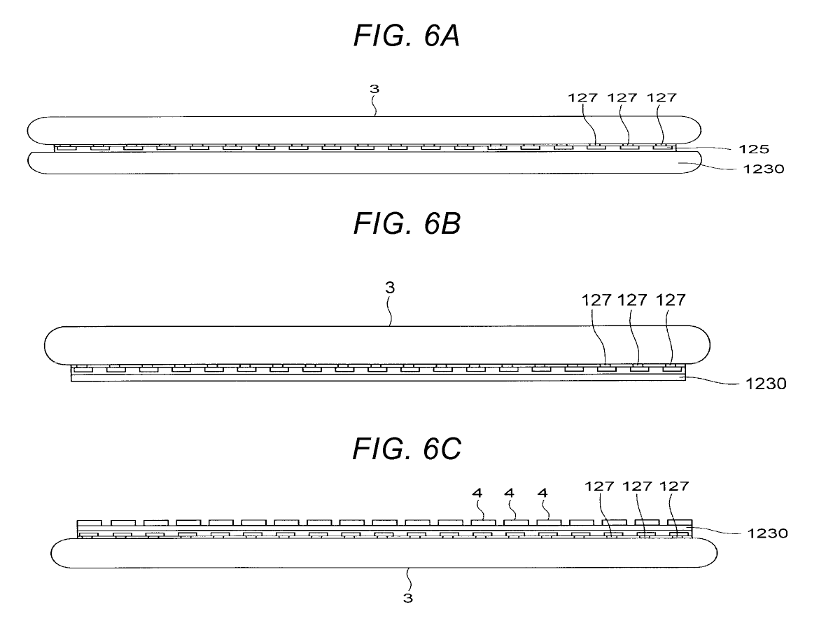

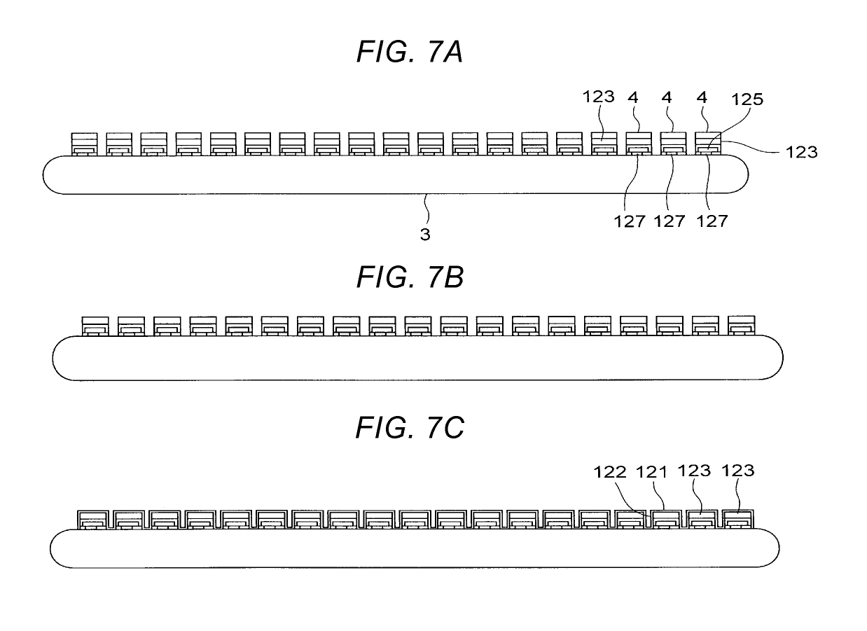

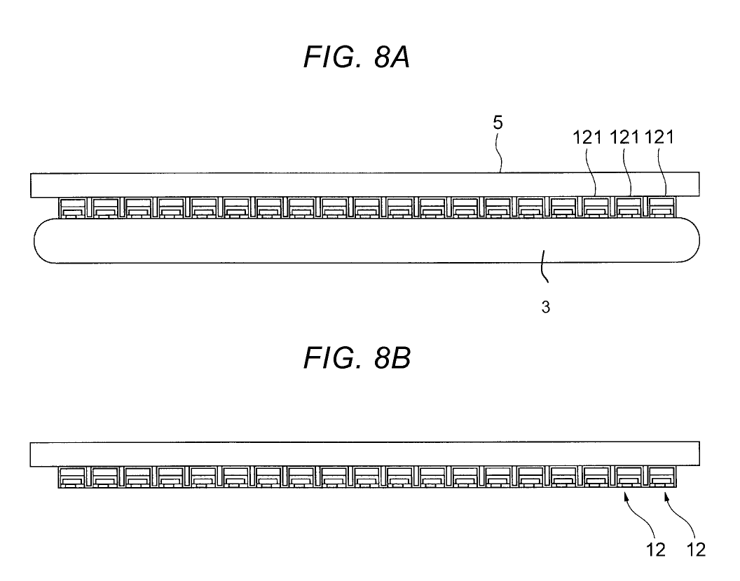

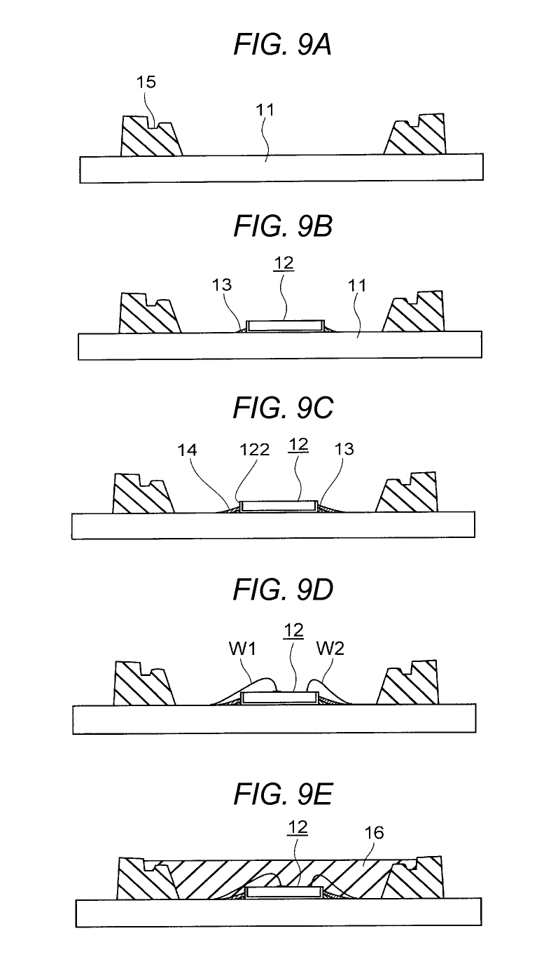

FIGS. 3A to 3C are a cross-sectional view of a structure during manufacturing of the light emitting device 1 according to the embodiment. FIGS. 4A to 4C are a cross-sectional view of the structure during the manufacturing of the light emitting device 1, following FIG. 3C. FIGS. 5A to 5C are a cross-sectional view of the structure during the manufacturing of the light emitting device 1, following FIG. 4C. FIGS. 6A to 6C are a cross-sectional view of the structure during the manufacturing of the light emitting device 1, following FIG. 5C. FIGS. 7A to 7C are a cross-sectional view of the structure during the manufacturing of the light emitting device 1, following FIG. 6C. FIGS. 8A and 8B are a cross-sectional view of the structure during the manufacturing of the light emitting device 1, following FIG. 7C. FIGS. 9A to 9E are a cross-sectional view of the structure during the manufacturing of the light emitting device 1, following FIG. 8B. The method of manufacturing the light emitting device 1 according to the embodiment will be described using FIGS. 3A to 9E.

In the method of manufacturing the light emitting device 1 according to the embodiment, as illustrated in FIG. 3A, a large substrate 2 is prepared in which a plurality of light emitting elements 12 may be formed. The substrate 2 may be, for example, a Si substrate, a SiC substrate, or a sapphire substrate.

As illustrated in FIG. 3B, a large n-type nitride semiconductor layer 128, a large light emitting layer 127, and a large p-type nitride semiconductor layer 126 are sequentially formed on the substrate 2. Each layer may be formed, for example, through a metal organic chemical vapor deposition (MOCVD) method.

As illustrated in FIG. 3C, a lower electrode layer 125, formed of Ag, Ni, or Al, is patterned on the p-type nitride semiconductor layer 126. The lower electrode layer 125 may be formed, for example, through etching of a metal thin film using the photolithography technique. Although FIG. 3C illustrates one lower electrode layer 125 representatively, the lower electrode layers 125 are actually patterned for every light emitting element 12 on the substrate 2.

As illustrated in FIG. 4A, a large joint layer 124, formed o SiO2, is formed on the lower electrode layer 125 for every light emitting element 12. The formed joint layer 124 is flattened through the CMP.

As illustrated in FIG. 4B, a base substrate 1230, which is a large supporting substrate 123, is adhered to the joint layer 124. The base substrate 1230 may be adhered there, for example, through silicon fusion bonding.

Next, as illustrated in FIG. 4C, the substrate 2 is removed. The substrate 2 may be removed, for example, through grinding or etching.

As illustrated in FIG. 5A, the large light emitting layer 127 is patterned into the light emitting layer 127 for every light emitting element 12. Then, surface processing such as formation of the light extraction surface 1281 is performed on the light emitting layer 127 for every light emitting element 12. The light emitting layer 127 for every light emitting element 12 may be patterned, for example, through the etching using the photolithography technique. The processing of the light extraction surface 1281, that is, the roughening processing may be performed, for example, through wet etching using alkali aqueous solution or dry etching. In FIGS. 5A to 5C, the light extraction surface 1281 is not illustrated.

As illustrated in FIG. 5B, for example, the protective layer 1211, which is formed of SiO₂, is formed on the light emitting layer 127 for every light emitting element 12. The protective layer 1211 may be patterned, for example, through the etching using the photolithography technique.

As illustrated in FIG. 5C, for example, the p-type pad electrode 1210, which is formed of Al, is formed on the lower electrode layer 125. Further, the n-type pad electrode 129 is formed on the n-type nitride semiconductor layer 128. The p-type pad electrode 1210 and the n-type pad electrode 129 are formed, for example, through the etching using the photolithography technique.

Next, as illustrated in FIG. 6A, the base substrate 1230 with the light emitting layers 127 patterned for every light emitting element 12 in the processes of FIGS. 3A to 5C is bonded to a substrate 3 for dicing on the side of the light emitting layer 127. The bonding may be performed, for example, with an adhesive material. FIGS. 6A to 8B omit the illustration of components other than the light emitting layer 127 and the lower electrode layer 125.

As illustrated in FIG. 6B, the base substrate 1230 is reduced in thickness suitable for being accommodated into a package. The thickness of the base substrate 1230 may be reduced, for example, through the grinding.

As illustrated in FIG. 6C, a resist 4 indicating a dicing line is patterned on the base substrate 1230. The resist 4 may be patterned, for example, through the etching using the photolithography technique.

As illustrated in FIG. 7A, the base substrate 1230 is etched through the dry etching in accordance with the opening pattern (dicing line) of the resist 4. The base substrate 1230 is divided into the supporting substrates 123 for every light emitting element 12 (individual pieces, singulation) on the substrate 3 for dicing through the dry etching.

As illustrated in FIG. 7B, the resist 4 is removed.

As illustrated in FIG. 7C, for example, Au, Ag, Pd, Pt or Al is used to form a first reflective layer 121 and a second reflective layer 122 at once on the supporting substrates 123 for every light emitting element 12. The first reflective layer 121 and the second reflective layer 122 may be formed, for example, through the sputtering or evaporation.

Next, as illustrated in FIG. 8A, a pick-up laminate film 5 is attached to the first reflective layers 121 for every light emitting element 12.

As illustrated in FIG. 8B, the substrate 3 for dicing is removed, and the respective light emitting elements 12 are picked up. As a result, the respective light emitting elements 12 can be manufactured.

Then, as illustrated in FIG. 9A, a mold resin layer 15 is formed on the frame 11. The mold resin layer 15 maybe formed, for example, through the transfer molding process. The mold resin layer 15 may contain a high reflective material such as TiO₂.

As illustrated in FIG. 9B, the light emitting element 12 is mounted on the frame 11, using a light absorptive adhesive layer 13.

As illustrated in FIG. 9C, a covering resin 14 including a high reflective material is formed on the top surface of the light absorptive adhesive layer 13. The covering resin 14 may be formed, for example, through the potting of a potting resin. Here, since in the light emitting element 12, the second reflective layer 122 secures the reflectance on the side surface, the use amount of the covering resin 14 maybe reduced to a small amount enough to just cover the adhesive layer 13.

As illustrated in FIG. 9D, the light emitting element 12 is bonded by wires. Specifically, one end of a first bonding wire W1 is connected to the n-type pad electrode 129, and the other end of the first bonding wire W1 is connected to the cathode portion of the frame 11. Further, one end of a second bonding wire W2 is connected to the p-type pad electrode 1210, and the other end of the second bonding wire W2 is connected to the anode portion of the frame 11. Since the use amount of the covering resin 14 including a high reflective material can be reduced to a small amount, the p-type pad electrode 1210 and the n-type pad electrode 129 are not covered with the covering resin 14. Thus, the wire bonding may be properly performed.

As illustrated in FIG. 9E, the light emitting element is sealed by a fluorescent material layer 16. The fluorescent material layer 16 is formed, for example, through the potting.

In the method of manufacturing the light emitting device 1 according to the embodiment, the dry etching is used to singulate the light emitting element 12, hence to narrow the width of the dicing line. Since the width of the dicing line may be narrowed, the number of the light emitting elements 12 produced from a single substrate may be increased.

Further, as compared with the case of dicing by a blade, the side surface 123b (cut-off surface) of the supporting substrate 123 may be flattened. Since the side surface 123b may be flattened, the second reflective layer 122 may be properly attached to the side surface 123b (favorable coatability or adhesiveness) when forming the second reflective layer 122. As the result of the good attachment of the second reflective layer 122 to the side surface 123b, production yield may be further improved.

Further, since the first reflective layer 121 and the second reflective layer 122 may be formed of the same material at once, material cost and the number of manufacturing processes may be reduced.

Since the second reflective layer 122 secures the reflectance on the side surface of the light emitting element 12, the use amount of the covering resin 14 including a high reflective material to be positioned on the side surface of the light emitting element 12 may be reduced. The use amount of the covering resin 14 may be reduced as described above, which may inhibit the covering resin 14 from covering the p-type pad electrode 1210 and the n-type pad electrode 129. Since the covering resin 14 may not cover the p-type pad electrode 1210 and the n-type pad electrode 129, the wire bonding may be properly performed through the pad electrodes 129 and 1210.

As mentioned above, by the manufacturing method according to the embodiment, the light emitting device 1 with the proper wire bonding may be manufactured, hence to improve the production yield.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A light emitting device comprising:
a frame;
a light emitting element provided above the frame and including a substrate, a light emitting layer provided above the substrate, a first reflective layer provided on a bottom surface of the substrate, a second reflective layer provided on a side surface of the substrate, and an electrode; and
a bonding wire with one end electrically connected to the electrode and another end electrically connected to the frame.

2. The device according to claim 1, wherein
the light emitting element further includes a lower electrode layer provided between the substrate and the light emitting layer, and
the lower electrode layer reflects light emitted from the light emitting layer.

3. The device according to claim 2, wherein
the light emitting element further includes an insulating film provided between the substrate and the lower electrode layer, to bond the substrate to the lower electrode layer.

4. The device according to claim 3, wherein
the second reflective layer is provided along the side surface of the substrate and a side surface of the insulating film.

5. The device according to claim 4, wherein
the insulating film includes a wall portion protruding upward in a side end portion of the insulating film, and
the second reflective layer extends to a side surface of the wall portion.

6. The device according to claim 5, wherein
the light emitting element further includes:
a first nitride semiconductor layer provided on a top surface of the light emitting layer, and
a second nitride semiconductor layer provided between the light emitting layer and the lower electrode layer;
the electrode includes:
a first electrode provided on a top surface of the first nitride semiconductor layer, to be electrically connected to the first nitride semiconductor layer, and
a second electrode provided on a top surface of a portion of the lower electrode layer that extends in a sideward direction more than the second nitride semiconductor layer, to be electrically connected to the second nitride semiconductor layer through the lower electrode layer; and
the bonding wire includes:
a first bonding wire electrically connected to the first electrode, and
a second bonding wire electrically connected to the second electrode.

7. The device according to claim 1, wherein
the substrate contains Si.

8. The device according to claim 1, further comprising:
an adhesive layer that bonds the light emitting element to a top surface of the frame, and
a covering resin containing a reflective material that covers the adhesive layer provided between the top surface of the frame and the second reflective layer.

9. The device according to claim 8, wherein a light absorbency index of the adhesive layer is larger than a light absorbency index of the covering resin.

10. A method of manufacturing a light emitting device comprising:
bonding a base substrate, a plurality of light emitting layers and electrodes provided on an upper portion of the base substrate, to a dicing substrate that is to be diced from an upper side of the base substrate;
separating the base substrate bonded to the dicing substrate into pieces;
forming a first reflective layer on a bottom surface of each piece of the base substrate and a second reflective layer on a side surface of each piece of the base substrate;
bonding one of the pieces having the first and second reflective layers to a top surface of a frame using an adhesive layer; and
electrically connecting the electrode bonded to the one of the pieces having the first and second reflective layers with a bonding wire.

11. The method according to claim 10, further comprising:
covering the adhesive layer provided between the top surface of the frame and the second reflective layer, with a covering resin containing a reflective material.

12. The method according to claim 11, wherein a light absorbency index of the adhesive layer is higher than a light absorbency index of the covering resin.

13. The method according to claim 10, further comprising:
cutting off the base substrate using dry etching.
